(19) United States
(12) Patent Application Publication
(10) Pub. No.: US 2024/0282818 A1
(43) Pub. Date: Aug. 22, 2024

(54) SEMICONDUCTOR DEVICE AND MANUFACTURING METHOD OF SEMICONDUCTOR DEVICE

(71) Applicant: FUJI ELECTRIC CO., LTD., Kanagawa (JP)

(72) Inventor: Naoki MITAMURA, Matsumoto-city (JP)

(21) Appl. No.: 18/395,660

(22) Filed: Dec. 25, 2023

(30) Foreign Application Priority Data
Feb. 21, 2023 (JP) 2023-025124

(51) Int. Cl. H01L 29/08; H01L 21/265; H01L 21/266; H01L 29/40; H01L 29/66; H01L 29/739

(52) U.S. Cl. CPC H01L 29/0804; H01L 21/26513; H01L 21/266; H01L 29/407; H01L 29/66348; H01L 29/7397

(57) ABSTRACT

Provided is a semiconductor device where the emitter region is provided to be in contact with a side wall of the gate trench portion and terminates without extending to a first trench portion opposing to the gate trench portion from among the plurality of trench portions in a trench array direction, and wherein the contact region is provided from an end portion of the emitter region to a side wall of the first trench portion in the trench array direction.

The contents of the following patent application(s) are incorporated herein by reference:
NO. 2023-025124 filed in JP on Feb. 21, 2023

### BACKGROUND

### 1. Technical Field

The present invention relates to a semiconductor device and a manufacturing method of the semiconductor device.

### 2. Related Art

Patent Literature 1 discloses a semiconductor device including a transistor portion including emitter layers of N+ type and contact layers of P+ type alternately provided on a front surface of a semiconductor substrate.

### PRIOR ART LITERATURE

### Patent Literature

Patent Literature 1: Japanese Patent Application Publication No. Hei. 11-345969

### BRIEF DESCRIPTION OF THE DRAWINGS

FIG. 1A is a top view illustrating an example of a semiconductor device 100 according to the example.

FIG. 1B is a diagram illustrating an example of the cross section taken along the line a-a in FIG. 1A.

FIG. 1C is a diagram illustrating an example of the cross section taken along the line b-b in FIG. 1A.

FIG. 2A is a diagram illustrating an example of correlation between a length of the emitter region 12 in the extending direction and dl/dt.

FIG. 2B is a diagram illustrating an example of correlation between dl/dt and a turn on loss Eon.

FIG. 3A is a top view illustrating an example of a semiconductor device 1100 according to the comparative example.

FIG. 3B is a diagram illustrating an example of the cross section taken along the line a′-a′ in FIG. 3A.

FIG. 4 is a top view illustrating a modification example of the semiconductor device 100.

FIG. 5 is a top view illustrating a modification example of the semiconductor device 100.

FIG. 6 is a diagram illustrating an example of a manufacturing method of the semiconductor device 100.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention.

In the present specification, one side in a direction parallel to a depth direction of a semiconductor substrate is referred to as ‘upper’ or ‘front’ and the other side is referred to as ‘lower’ or ‘rear’. One surface of two principal surfaces of a substrate, a layer, or other member is referred to as a front surface, and the other surface is referred to as a back surface. “Upper” and “lower” directions are not limited to a direction of gravity, or a direction in which a semiconductor device is mounted.

In the present specification, technical matters may be described using orthogonal coordinate axes consisting of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a −Z axis direction are directions opposite to each other. When the Z axis direction is described without describing the signs, it means that the direction is parallel to the +Z axis and the −Z axis.

In the present specification, orthogonal axes parallel to the front surface and the back surface of the semiconductor substrate are referred to as the X axis and the Y axis. In addition, an axis perpendicular to the front surface and the back surface of the semiconductor substrate is referred to as the Z axis. In the present specification, the direction of the Z axis may be referred to as the depth direction. In addition, in the present specification, a direction parallel to the front surface and the back surface of the semiconductor substrate may be referred to as a horizontal direction, including an X axis direction and a Y axis direction.

In the present specification, a case where a term such as “same” or “equal” is mentioned may include a case where an error due to a variation in manufacturing or the like is included. The error is, for example, within 10%.

In the present specification, a conductivity type of a doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting the conductivity type of the N type, or a semiconductor presenting the conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}−N_{A}.

The donor has a function of supplying electrons to a semiconductor. The acceptor has a function of receiving electrons from the semiconductor. The donor and the acceptor are not limited to the impurities themselves. For example, a VOH defect which is a combination of a vacancy (V), oxygen (O), and hydrogen (H) existing in the semiconductor functions as the donor that supplies electrons.

In the present specification, a description of a P+ type or an N+ type means a higher doping concentration than that of the P type or the N type, and a description of a P− type or an N− type means a lower doping concentration than that of the P type or the N type. Further, in the specification, a description of a P++ type or an N++ type means a higher doping concentration than that of the P+ type or the N+ type.

A chemical concentration in the present specification refers to the concentration of impurities, which is measured regardless of the state of electrical activation. The chemical concentration can be measured by, for example, secondary ion mass spectrometry (SIMS). The net doping concentration described above can be measured by capacitance-voltage profiling (CV profiling). Further, a carrier concentration measured by spreading resistance profiling (SRP method) may be set as the net doping concentration. The carrier concentration measured by the CV profiling or the SRP method may be a value in a thermal equilibrium state. Further, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration.

Further, when a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in carrier mobility occurs when carriers are scattered due to disorder (disorder) of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

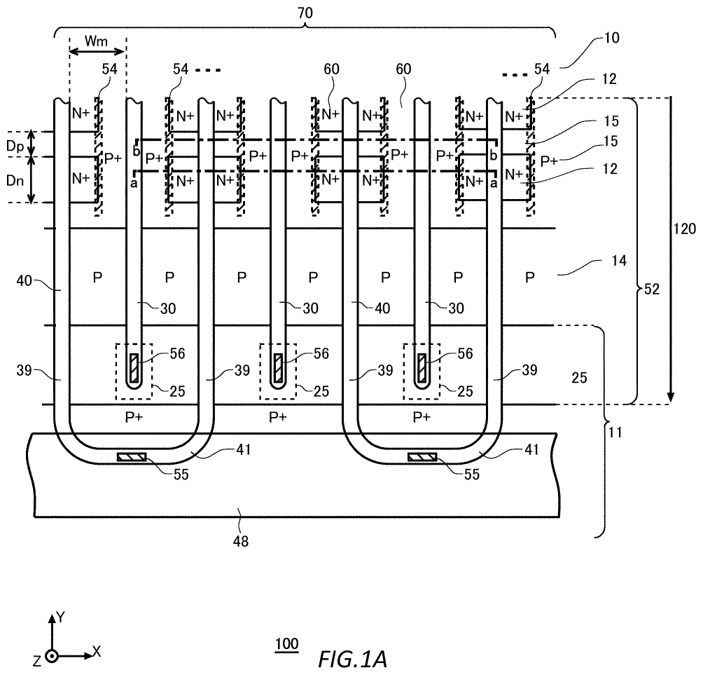

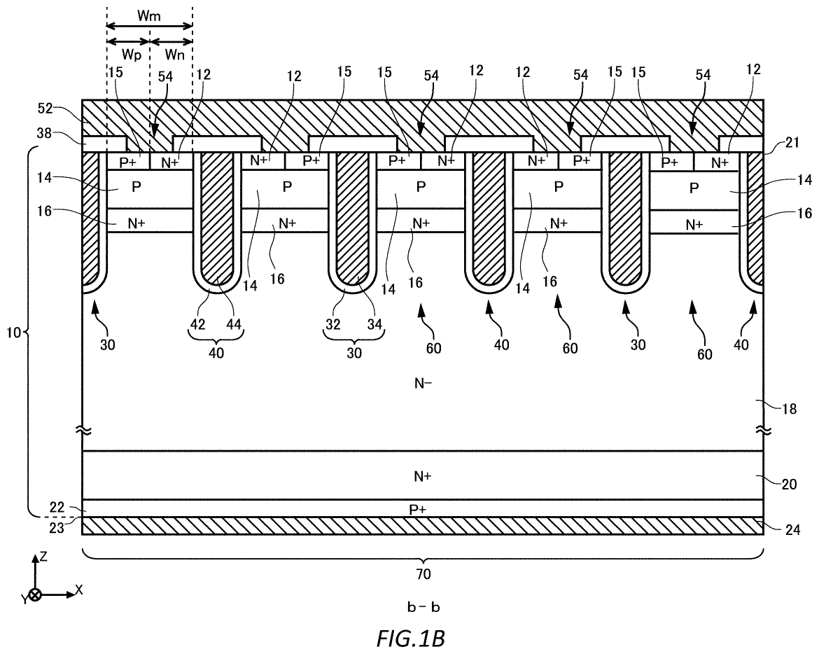

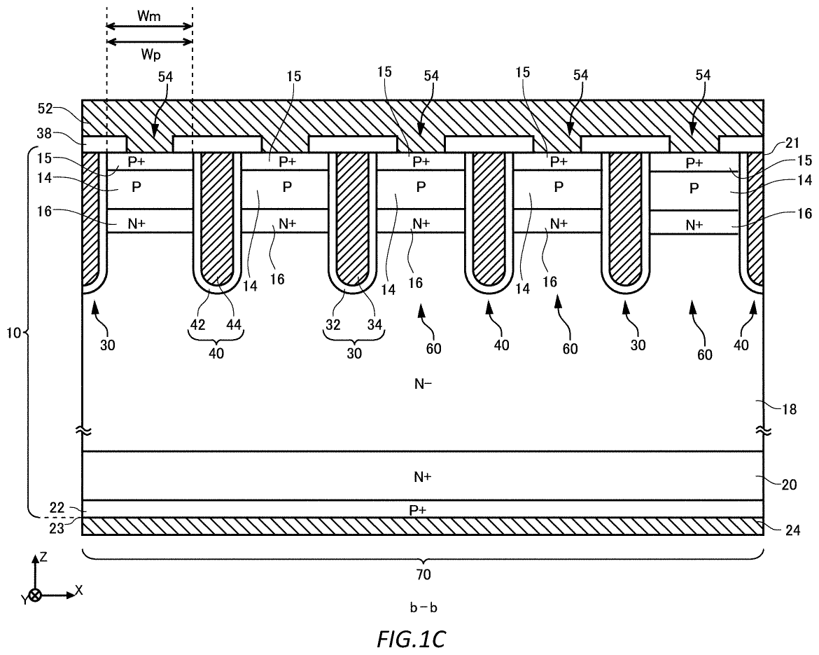

FIG. 1A is a top view illustrating an example of a semiconductor device 100 according to the example. FIG. 1A illustrates a position of each member projected on a front surface of a semiconductor substrate. FIG. 1A shows merely some members of the semiconductor device 100, and omits some members.

The semiconductor device 100 includes a semiconductor substrate. As simply used herein, unless otherwise specified, a top view means a view from the side of the front surface of the semiconductor substrate. The semiconductor substrate of the present example has two sets of end sides opposite to each other in a top view. In FIG. 1A, the X axis and the Y axis are parallel to any of the end sides. In addition, the Z axis is perpendicular to the front surface of the semiconductor substrate.

The semiconductor substrate is provided with an active portion 120. The active portion 120 is a region in which a main current flows in a depth direction (Z axis direction) between the front surface and the back surface of the semiconductor substrate when the semiconductor device 100 is in operation. In the present example, a region corresponding to an emitter electrode 52 which will be described later is an active portion 120.

The active portion 120 is provided with a transistor portion 70 including a transistor device such as an IGBT. The active portion 120 may further be provided with a diode portion including a diode device such as a free wheel diode (FWD). In the transistor portion 70, an emitter region of the N type, a base region of the P type, and a gate structure having a gate conductive portion and a gate dielectric film are periodically arranged in the front surface side of the semiconductor substrate.

The semiconductor device 100 may have one or more pads above the semiconductor substrate. The semiconductor device 100 may have a pad such as a gate pad, an anode pad, a cathode pad, and a current detection pad. Each pad is arranged in a region in the vicinity of the end side. The region in the vicinity of the end side refers to a region between the end side and the emitter electrode 52 in a top view. When the semiconductor device 100 is mounted, each pad may be connected to an external circuit via a wiring such as a wire.

A gate potential is applied to the gate pad. The gate pad is electrically connected to a conductive portion of a gate trench portion of the active portion 120. The semiconductor device 100 includes a gate runner 48 that electrically connects the gate pad and the gate trench portion.

The gate runner 48 is arranged between the active portion 120 and the end side of the semiconductor substrate in a top view. The gate runner 48 of the present example surrounds the active portion 120 in a top view. A region surrounded by the gate runner 48 in a top view may be set as the active portion 120.

The gate runner 48 is arranged above the semiconductor substrate. The gate runner 48 of the present example may be formed of polysilicon doped with impurities, or the like. The gate runner 48 is electrically connected to the gate conductive portion provided inside the gate trench portion via a gate dielectric film. The gate runner 48 supplies a gate voltage applied to the gate pad to the transistor portion 70.

The semiconductor device 100 in the present example includes an edge termination structure provided around an outer circumference of the active portion 120. The edge termination structure of the present example is arranged between the gate runner 48 and the end side. The edge termination structure reduces electric field strength on the front surface side of the semiconductor substrate.

The edge termination structure may further include at least one of a field plate and an RESURF which are annularly provided to surround the active portion 120. The field plate may be the same material as that of the emitter electrode 52.

Furthermore, the semiconductor device 100 may include a temperature sensing unit (not illustrated) that is a PN junction diode formed of polysilicon or the like, and a current detection unit (not illustrated) configured to simulate an operation of the transistor portion provided in the active portion 120.

The semiconductor device 100 includes a gate trench portion 40, a dummy trench portion 30, a well region 11, an emitter region 12, a base region 14, and a contact region 15 which are provided in the front surface side of the semiconductor substrate. The gate trench portion 40 and the dummy trench portion 30 each are an example of the trench portion.

In addition, the semiconductor device 100 of the present example includes an emitter electrode 52 provided above the front surface of the semiconductor substrate. An interlayer dielectric film is provided between the emitter electrode 52 and the gate runner 48 and the front surface of the semiconductor substrate, although it is omitted in FIG. 1A. In the interlayer dielectric film of the present example, contact holes 54, 55, and 56 are provided to extend through the interlayer dielectric film. In FIG. 1A, each contact hole is hatched with oblique lines.

The emitter electrode 52 is provided above the gate trench portion 40, the dummy trench portion 30, the well region 11, the emitter region 12, the base region 14, and the contact region 15. The emitter electrode 52 is electrically connected to the emitter region 12, the base region 14, and the contact region 15 for the front surface of the semiconductor substrate through the contact hole 54.

In addition, the emitter electrode 52 is connected to a dummy conductive portion in the dummy trench portion 30 through the contact hole 56. A connection portion 25 formed of a conductive material such as polysilicon doped with impurities may be provided between the emitter electrode 52 and the dummy conductive portion. The connection portion 25 is provided at the front surface of the semiconductor substrate via a dielectric film such as the interlayer dielectric film and a dummy dielectric film of the dummy trench portion 30.

The gate runner 48 and the emitter electrode 52 are electrically separated by an insulator such as the interlayer dielectric film and an oxide film. The gate runner 48 of the present example is provided from a position below the contact hole 55 to an edge portion 41 of the gate trench portion 40. At the edge portion 41 of the gate trench portion 40, the gate conductive portion is exposed to the front surface of the semiconductor substrate to be connected to the gate runner 48. The gate runner 48 is connected to a gate conductive portion in the gate trench portion 40 in the front surface of the semiconductor substrate. The gate runner 48 is not electrically connected to the dummy conductive portion in the dummy trench portion 30 and the emitter electrode 52.

The emitter electrode 52 is formed of a conductive material containing metal. For example, the emitter electrode and the gate metal layer are formed of an alloy containing aluminum or aluminum as a main component (for example, an aluminum-silicon alloy or the like). Each electrode may have a barrier metal formed of titanium, a titanium compound, or the like as an underlying layer of a region formed of aluminum or the like.

The emitter electrode 52 may be connected to a plug provided within the contact hole. The plug may include a barrier metal provided on a side wall of the contact hole and tungsten embedded within the contact hole to contact the barrier metal.

The plug is provided in the contact hole which contacts the contact region 15 or the base region 14. Below the contact hole provided with the plug, a plug region of the P++ type having a doping concentration higher than that of the contact region 15 may also be provided. The plug region improves latch up withstand capability by improving a contact resistance between the barrier metal and the contact region 15.

The well region 11 overlaps the gate runner 48 to extend in the outer circumference of the active portion 120, and is annularly provided in a top view. The well region 11 extends over a predetermined width even in a range not overlapping the gate runner 48, and is annularly provided in a top view. The well region 11 of the present example is provided from an end of the contact hole 54 in the extending direction (Y axis direction) toward the gate runner 48 side. The well region 11 is a region of a second conductivity type in which the doping concentration is higher than the base region 14. The gate runner 48 is electrically insulated from the well region 11.

The base region 14 of the present example is of a P type, and the well region 11 is of a P+ type. In addition, the well region 11 is formed from the front surface of the semiconductor substrate to a position deeper than a lower end of the base region 14. The base region 14 may be provided in contact with the well region 11. Therefore, the well region 11 is electrically connected to the emitter electrode 52.

The transistor portion 70 includes a plurality of trench portions arrayed in an array direction (X axis direction). In the transistor portion 70 of the present example, one or more gate trench portions 40 are provided along the array direction.

The gate trench portion 40 of the present example may have two extending portions 39 that extends along an extending direction (Y axis direction) perpendicular to the array direction (trench portions in a straight shape along the extending direction), and an edge portion 41 that connects the two extending portions 39.

At least a part of the edge portion 41 may be provided in a curved shape in a top view. The end portions of two extending portions 39 in the Y axis direction are connected to the gate runner 48 by the edge portion 41 to function as a gate electrode for the gate trench portion 40. On the other hand, the edge portion 41 is formed in a curved shape so that the electric field strength at the end portion can be more reduced than the one at the end portion at which the extending portion 39 terminates.

In the transistor portion 70, one or more gate trench portions 40 and one or more dummy trench portions 30 may be alternately provided along the array direction. In the transistor portion 70, the dummy trench portions 30 are provided between the respective extending portions 39 of the gate trench portions 40. One dummy trench portion 30 may be provided or a plurality of dummy trench portions 30 may be provided between the respective extending portions 39.

Alternatively, the dummy trench portion 30 may not be provided and the gate trench portion 40 may also be provided between the respective extending portions 39. With such a structure, the electron current from the emitter region 12 can be increased, so that an ON voltage is reduced.

The dummy trench portion 30 may have a straight shape extending in the extending direction, or may have an extending portion and an edge portion similar to the gate trench portion 40. The semiconductor device 100 illustrated in FIG. 1A only includes the dummy trench portions 30 in a straight shape arrayed without an edge portion. However, in another example, the semiconductor device 100 may also include the dummy trench portion 30 including a curved edge portion in a top view.

A diffusion depth of the well region 11 may be deeper than the depth of the gate trench portion 40 and the dummy trench portion 30. End portions of the gate trench portion 40 and the dummy trench portion 30 in the Y axis direction are provided in the well region 11 in a top view. In other words, the bottom in the depth direction of each trench portion is covered with the well region 11 at the end portion in the Y axis direction of each trench portion. In addition, the trench portion provided at the end portion in an X axis direction may be covered with the well region 11. With this configuration, the electric field strength on the bottom portion of each trench portion can be reduced.

A mesa portion 60 is provided between trench portions in the array direction. The mesa portion 60 refers to a region interposed between the trench portions in the semiconductor substrate. As an example, a depth position of the mesa portion 60 is from the front surface of the semiconductor substrate to a bottom portion of the trench portion. The mesa portion 60 of the present example is provided to be located between the trench portions adjacent to each other in the X axis direction and to extend along the trench portion in the extending direction (Y axis direction) on the front surface of the semiconductor substrate.

Each mesa portion 60 is provided with the base region 14. Each mesa portion 60 is provided with the emitter region 12 of the first conductivity type and the contact region 15 of the second conductivity type in a region between the base regions 14 in a top view. The emitter region 12 of the present example is an N+ type, and the contact region 15 is a P+ type. The emitter region 12 and the contact region 15 may be provided between the base region 14 and the front surface of the semiconductor substrate in the depth direction of the semiconductor substrate. The doping concentration of the base region 14 of the present example is equal to or greater than 1E17 cm⁻³ and equal to or smaller than 1E18 cm⁻³, the doping concentration of the emitter region 12 is equal to or greater than 2E19 cm⁻³ and equal to or smaller than 4E20 cm⁻³, and the doping concentration of the contact region 15 is equal to or greater than 1E19 cm⁻³ and equal to or smaller than 2E20 cm⁻³.

The mesa portion 60 has the emitter region 12 exposed to the front surface of the semiconductor substrate. The emitter region 12 of the present example is provided to be in contact with a side wall of the gate trench portion 40. The emitter region 12 of the present example extends from the gate trench portion 40 and terminates without extending to the adjacent dummy trench portion 30 in the array direction. The contact region 15 of the present example is provided from an end portion of the emitter region 12 to a side wall of the dummy trench portion 30 in the array direction.

In the present example, a length of the emitter region 12 in the extending direction is Dn, and a length of the contact region 15 in the extending direction is Dp. Both of the length Dn of the emitter region 12 in the extending direction and the length Dp of the contact region 15 in the extending direction are greater than the width Wm of the mesa portion 60. Here, the width Wm of the mesa portion 60 refers to a distance from the side wall of the trench portion to the side wall of the opposing trench portion in the array direction.

On the side wall of the gate trench portion 40, the length Dn of the emitter region 12 in the extending direction is greater than the length Dp of the contact region 15 in the extending direction. The length Dn of the emitter region 12 in the extending direction is equal to or greater than 0.5 times and equal to or smaller than ten times the length Dp of the contact region 15 in the extending direction.

Note that the dummy trench portion 30 is an example of the first trench portion opposing to the gate trench portion 40 with which the emitter region 12 is in contact, from among a plurality of trench portions. The emitter region 12 of the present example is provided to be spaced apart from the side wall of the dummy trench portion 30.

In addition, the emitter regions 12 of the present example are discretely provided in the extending direction in a top view of the semiconductor substrate. In a region in which the emitter region 12 is not provided on the side wall of the gate trench portion 40, the contact region 15 is provided to extend from the gate trench portion 40 to the adjacent dummy trench portion 30 across the mesa portion 60 in the array direction. That is, the emitter regions 12 are provided to be surrounded by the contact region 15 to form a dotted pattern in a top view of the semiconductor substrate.

On the upper side of each mesa portion 60, the contact hole 54 is provided. The contact hole 54 is arranged in the region interposed between the base regions 14 in the extending direction. The contact hole 54 may be arranged at the center of the mesa portion 60 in the array direction.

FIG. 1B is a diagram illustrating an example of the cross section taken along the line a-a in FIG. 1A. The cross section taken along the line a-a is an XZ plane passing through the emitter region 12 and the contact region 15. The semiconductor device 100 of the present example includes the semiconductor substrate 10, the interlayer dielectric film 38, the emitter electrode 52, and the collector electrode 24 in the cross section. The emitter electrode 52 is provided on the upper surfaces of the interlayer dielectric film 38 and the semiconductor substrate 10.

The collector electrode 24 is provided on the back surface 23 of the semiconductor substrate 10. The collector electrode 24 is formed of a conductive material such as metal. The depth direction in the present specification refers to a direction connecting the emitter electrode 52 and the collector electrode 24. The depth direction of the present example refers to the Z axis direction.

The semiconductor substrate 10 may be a silicon substrate, may be a silicon carbide substrate, or may be a nitride semiconductor substrate such as gallium nitride, or the like. In the present example, the semiconductor substrate 10 is a silicon substrate. The base region 14 of the P type is provided in the front surface 21 side of the semiconductor substrate 10 in the cross section.

In the cross section, in the front surface 21 side of the semiconductor substrate 10 in the transistor portion 70, the emitter region 12 of the N+ type, the contact region 15 of the P+ type, the base region 14 of the P type, and the accumulation region 16 of the N+ type are provided in the order from the front surface 21 side of the semiconductor substrate 10.

The thickness of the emitter region 12 of the present example is equal to or greater than 0.05 μm and equal to or smaller than 1.0 μm, and the thickness of the contact region 15 is equal to or greater than 0.05 μm and equal to or smaller than 2.0 μm. Here, the thickness refers to a distance from the front surface 21 of the semiconductor substrate 10 to a lower end of the region in the depth direction of the semiconductor substrate 10. In FIG. 1B, the contact region 15 and the emitter region 12 are illustrated to have the same thickness, although the thickness of the contact region 15 may be smaller than the thickness of the emitter region 12.

In the present example, the length of the emitter region 12 in the array direction is Wn, and the length of the contact region 15 in the array direction is Wp. The length Wn of the emitter region 12 in the array direction refers to a distance from the side wall of the gate trench portion 40 to the terminating position, that is, the boundary with the contact region 15. In FIG. 1B, the length Wp of the contact region 15 in the array direction refers to a distance from the side wall of the dummy trench portion 30 to the boundary with the emitter region 12. In FIG. 1B, the sum of the length Wn of the emitter region 12 and the length Wp of the contact region 15 is equal to the width Wm of the mesa portion 60.

The length Wn of the emitter region 12 in the array direction is equal to or greater than 0.1 μm and equal to or smaller than 3.0 μm. The length Wn of the emitter region 12 of the present example in the array direction is equal to or greater than 0.1 μm and equal to or smaller than 1.0 μm. The terminating position of the emitter region 12 in the array direction is located below the contact hole 54. That is, the contact hole 54 of the present example is provided above the boundary between the emitter region 12 and the contact region 15.

When the transistor portion 70 is in operation, a hole current from the collector region 22 goes up along the side wall of the gate trench portion 40, and then flows into the contact region 15 along the lower end of the emitter region 12. Therefore, a shorter travel distance along the lower end of the emitter region 12 in the path of the hole current promotes withdrawal of holes and improves the latch up withstand capability.

The emitter region 12 of the present example extends from the gate trench portion 40 and terminates to be in contact with the contact region 15 without extending to the dummy trench portion 30 in the array direction, such that the path of the hole current is shorter than the path when extending across the mesa portion 60 when the transistor portion 70 is in operation. Therefore, the latch up withstand capability can be ensured even if the length Dn of the emitter region 12 in the extending direction is larger.

In the transistor portion 70, the drift region 18 of the N− type is provided below the accumulation region 16. The accumulation region 16 having a higher concentration than the drift region 18 is provided between the drift region 18 and the base region 14, so that it is possible to increase a carrier injection enhancement effect (IE effect), thereby reducing the on voltage.

The accumulation region 16 of the present example is provided in each mesa portion 60 of the transistor portion 70. The accumulation region 16 may be provided to cover the entire lower surface of the base region 14 in each mesa portion 60. The buffer region 20 of the N+ type is provided below the drift region 18. A plurality of accumulation regions 16 may be provided in the depth direction.

The buffer region 20 is provided below the drift region 18. The doping concentration of the buffer region 20 is higher than the doping concentration of the drift region 18. The buffer region 20 may function as a field stop layer to prevent the depletion layer extending from the lower surface of the base regions 14 from reaching the collector region 22 of the P+ type. The collector region 22 of the P+ type is provided below the buffer region 20.

The one or more gate trench portions 40 and the one or more dummy trench portions 30 are provided in the front surface 21 side of the semiconductor substrate 10. Each trench portion is provided to extend from the front surface 21 of the semiconductor substrate 10 and extend through the base region 14 to reach the drift region 18. In a region in which at least any of the emitter region 12, the contact region 15 and the accumulation region 16 is provided, each trench portion reaches the drift region 18 extending through these regions.

The trench portion extending through the doping region is not limited to those manufactured in the order of forming the doping region and then forming the trench portion. The configuration of the trench portion extending through the doping region includes a configuration of the doping region being formed between the trench portions after forming the trench portion.

The gate trench portion 40 includes a gate dielectric film 42 and a gate conductive portion 44 provided in the front surface 21 side of the semiconductor substrate 10. The gate dielectric film 42 is provided to cover the inner wall of the gate trench portion 40. The gate dielectric film 42 may be formed by oxidizing or nitriding semiconductors on the inner wall of the gate trench portion 40. The gate conductive portion 44 is provided inside the gate dielectric film 42 in the gate trench portion 40. That is, the gate dielectric film 42 insulates the gate conductive portion 44 from the semiconductor substrate 10. The gate conductive portion 44 is formed of a conductive material such as polysilicon.

The gate conductive portion 44 includes a region opposite to the base region 14 intervening the gate dielectric film 42. The gate trench portion 40 in the cross section is covered by the interlayer dielectric film 38 on the front surface 21 of the semiconductor substrate 10. When a predetermined voltage is applied to the gate conductive portion 44, an inversion layer of electrons serving as a channel is formed on a surface layer of the interface of the base region 14 in contact with the gate trench.

The dummy trench portions 30 may have the same structure as the gate trench portions 40 in the cross section. The dummy trench portion 30 has a dummy trench, a dummy dielectric film 32, and a dummy conductive portion 34 which are provided on the front surface 21 side of the semiconductor substrate 10. The dummy dielectric film 32 is provided to cover an inner wall of the dummy trench. The dummy conductive portion 34 is provided in the dummy trench, and is provided on an inner side further than the dummy dielectric film 32. The dummy dielectric film 32 insulates the dummy conductive portion 34 from the semiconductor substrate 10. The dummy conductive portion 34 may be formed of the same material as the gate conductive portion 44.

FIG. 1C is a diagram illustrating an example of the cross section taken along the line b-b in FIG. 1A. The cross section taken along the line b-b is an XZ plane passing through the contact region 15. The cross section taken along the line b-b is the same as the cross section taken along the line a-a in FIG. 1B, aside from the emitter region 12 not provided on the front surface 21 of the semiconductor substrate 10.

As illustrated in FIG. 1C, in a region in which the emitter region 12 is not provided on the side wall of the gate trench portion 40, the contact region 15 is provided to extend from the gate trench portion 40 to the adjacent dummy trench portion 30 across the mesa portion 60 in the array direction. In FIG. 1C, the length Wp of the contact region 15 in the array direction is equal to the width Wm of the mesa portion 60. The hole current from the collector region 22 goes up along the side wall of the gate trench portion 40 so that holes are withdrawn in the contact region 15 to suppress the latch up.

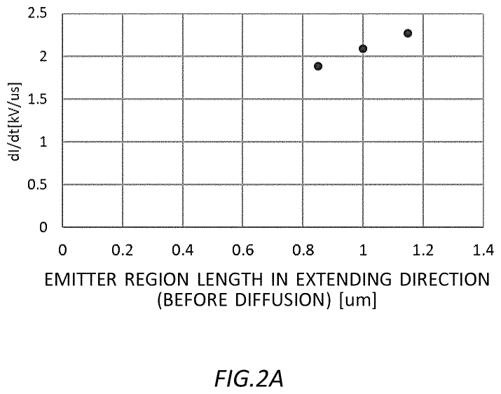

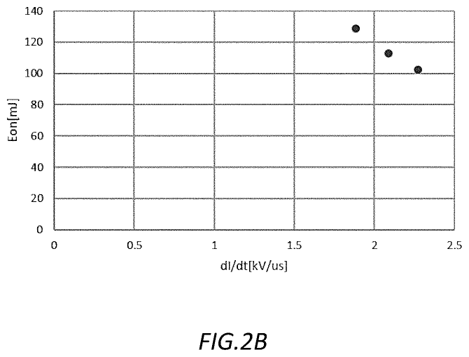

FIG. 2A is a diagram illustrating an example of correlation between a length of the emitter region 12 in the extending direction and dl/dt. The horizontal axis indicates the length [μm] of the emitter region 12 in the extending direction before diffusion and the vertical axis indicates dl/dt [kV/μs] when turned on. As can be seen from FIG. 2A, dl/dt when turned on is in proportion to the length of the emitter region 12 in the extending direction.

FIG. 2B is a diagram illustrating an example of correlation between dl/dt and a turn on loss Eon. The horizontal axis indicates dl/dt [kV/μs] when turned on and the vertical axis indicates the turn on loss Eon. As can be seen from FIG. 2B the turn on loss Eon is in inverse proportion to dl/dt when turned on. Thus, from FIG. 2A and FIG. 2B, a larger length of the emitter region 12 in the extending direction can more reduce the turn on loss Eon.

However, if the length of the emitter region 12 in the extending direction is increased, the path of the hole current when the transistor portion 70 is in operation is increased so that the latch up withstand capability is decreased. Therefore, it is desired to reduce the turn on loss Eon while ensuring the latch up withstand capability.

In addition, for a vehicle mount product, for example, the upper limit value of dl/dt when turned on may be determined. Therefore, dl/dt under the standard condition may need to be set lower when a fluctuation of dl/dt is large. Therefore, to reduce the fluctuation of dl/dt, it is desired to reduce the fluctuation of the lengths of the emitter region 12 and the contact region 15 in the extending direction.

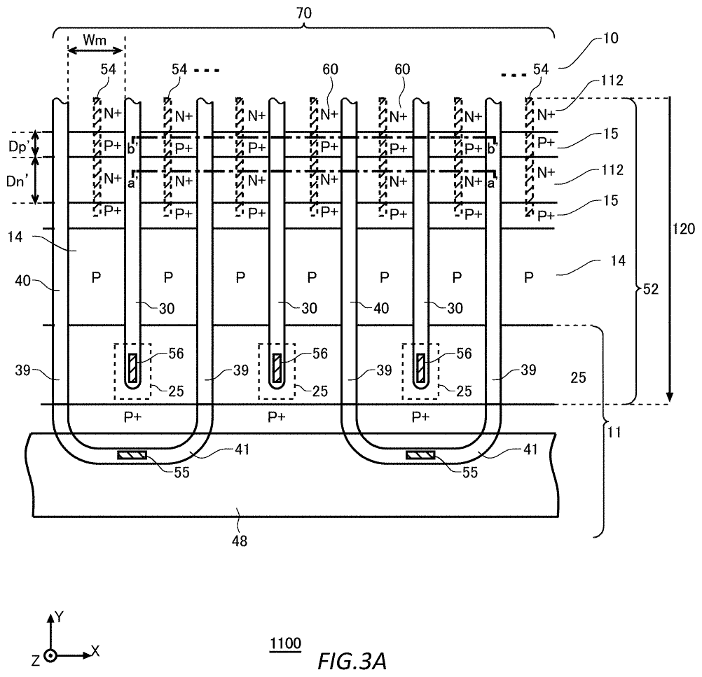

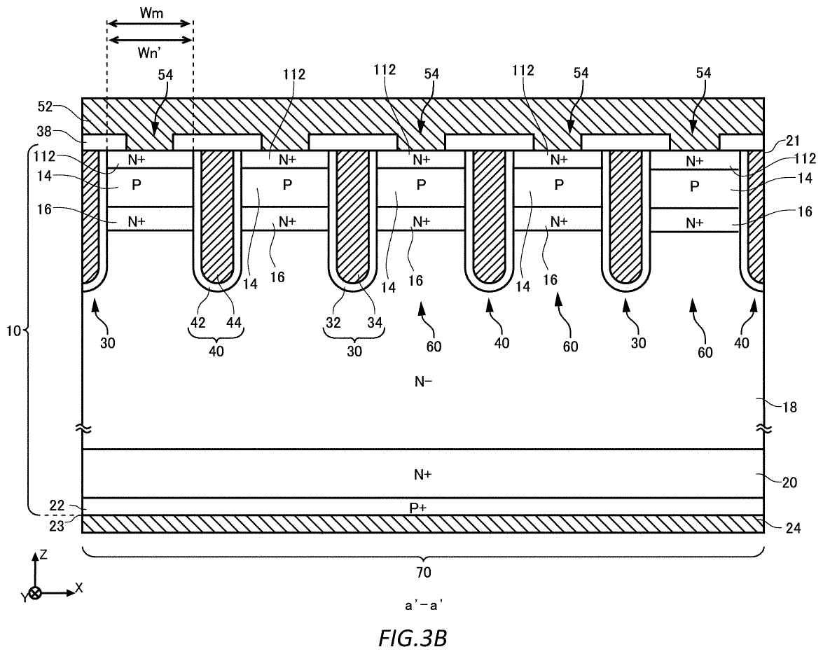

FIG. 3A is a top view illustrating an example of a semiconductor device 1100 according to the comparative example. Here, elements common with the semiconductor device 100 according to the example are provided with the same signs and the descriptions will be omitted.

FIG. 3B is a diagram illustrating an example of the cross section taken along the line a′-a′ in FIG. 3A. The cross section taken along the line a′-a′ is an XZ plane passing through the emitter region 112. Note that the cross section taken along the line b′-b′ in FIG. 3A is the same the XZ plane passing through the contact region 15 illustrated in FIG. 1C, and the illustration will therefore be omitted.

In the mesa portion 60 of the semiconductor device 1100, each of the contact region 15 and the emitter region 112 is provided from one trench portion to the other trench portion in the array direction. In the mesa portion 60 of the semiconductor device 1100, the contact regions 15 and the emitter regions 112 are alternately arranged in the extending direction. That is, the end portion of the emitter region 112 in the array direction is not in contact with the contact region 15, and the end portion in the extending direction is only in contact with the contact region 15.

The length of the emitter region 112 in the extending direction is Dn′, and the length in the array direction is Wn′. The length of the contact region 15 in the extending direction is Dp′. The length Wn′ of the emitter region 112 in the array direction is equal to the width Wm of the mesa portion 60. Both of the length Dn′ of the emitter region 112 in the extending direction and the length Dp′ of the contact region 15 in the extending direction are greater than the width Wm of the mesa portion 60. The ratio of the length Dn′ of the emitter region 112 in the extending direction to the length Dp′ of the contact region 15 in the extending direction may be the same as the ratio of the length Dn of the emitter region 12 in the extending direction to the length Dp of the contact region 15 in the extending direction.

As described above, when the transistor portion 70 is in operation, a hole current from the collector region 22 goes up along the side wall of the gate trench portion 40, and then flows into the contact region 15 along the lower end of the emitter region 112. Therefore, a shorter travel distance along the lower end of the emitter region 112 in the path of the hole current promotes withdrawal of holes and improves the latch up withstand capability.

The emitter region 112 of the semiconductor device 1100 extends from the gate trench portion 40 to the dummy trench portion 30 in the array direction. The length Wn′ of the emitter region 112 in the array direction is equal to the width Wm of the mesa portion 60. That is, the hole current travelling along the side wall of the gate trench portion 40 and reaching the lower end of the emitter region 112 cannot reach the contact region 15 even if it travels in the array direction so that it travels in the extending direction to flow into the contact region 15.

The length Dn′ of the emitter region 112 in the extending direction is greater than the width Wm of the mesa portion 60. Therefore, in the semiconductor device 1100, the path of the hole current when the transistor portion 70 is in operation is longer than that of the semiconductor device 100. Therefore, in the semiconductor device 1100, the length Dn′ of the emitter region 112 in the extending direction is required to be smaller than the length Dn of the emitter region 12 of the semiconductor device 100 in the extending direction to suppress the decrease of the latch up withstand capability.

On the other hand, as the emitter region 12 of the semiconductor device 100 extends from the gate trench portion 40 and terminates without extending to the adjacent dummy trench portion 30 in the array direction, the path of the hole current when the transistor portion 70 is in operation is not extended even if the length Dn of the emitter region 12 in the extending direction is larger so that the latch up withstand capability can be ensured. In this manner, in the semiconductor device 100, the length Dn of the emitter region 12 in the extending direction is larger such that the turn on loss Eon can be reduced while ensuring the latch up withstand capability.

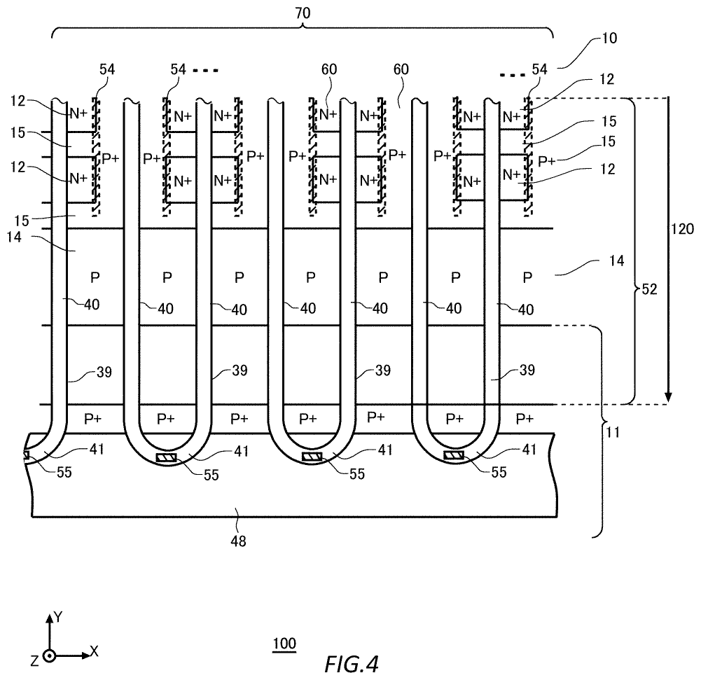

FIG. 4 is a top view illustrating a modification example of the semiconductor device 100. The semiconductor device 100 of the present example is different from the semiconductor device 100 illustrated in FIG. 1A with respect to the transistor portion 70 of the present example provided with a plurality of gate trench portions 40 and not provided with the dummy trench portion 30. Here, elements common with the semiconductor device 100 illustrated in FIG. 1A are provided with the same signs and the descriptions will be omitted.

The emitter region 12 of the present example extends from the gate trench portion 40 and terminates without extending to the adjacent gate trench portion 40 in the array direction. The contact region 15 of the present example is provided from an end portion of the emitter region 12 to a side wall of the gate trench portion 40 in the array direction.

In the present example, the gate trench portion 40 with which the emitter region 12 is not in contact is an example of the first trench portion opposing to the gate trench portion 40 with which the emitter region 12 is in contact, from among a plurality of trench portions. In the present example, the gate trench portions 40 with which the emitter region 12 is in contact and the gate trench portions 40 with which the emitter region 12 is not in contact are alternately arrayed in the array direction. Even in such a configuration, the path of the hole current when the transistor portion 70 is in operation is not extended so that the effect similar to that of the semiconductor device 100 illustrated in FIG. 1A can be obtained.

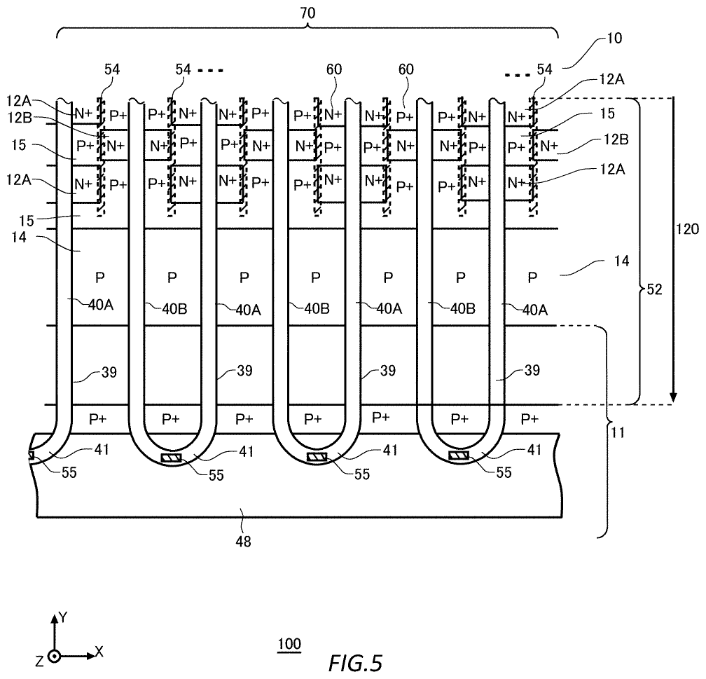

FIG. 5 is a top view illustrating a modification example of the semiconductor device 100. The semiconductor device 100 of the present example is the same as the semiconductor device 100 illustrated in FIG. 4 with respect to the transistor portion 70 of the present example provided with a plurality of gate trench portions 40 and not provided with the dummy trench portion 30. However, the present example is different from the semiconductor device 100 illustrated in FIG. 4 with respect to the gate trench portions 40 all of which have the side walls in contact with the emitter region 12. Here, elements common with the semiconductor device 100 illustrated in FIG. 1A or FIG. 4 are provided with the same signs and the descriptions will be omitted.

The emitter region 12 of the present example includes: a first emitter region 12A which is provided to be in contact with the side wall of the gate trench portion 40A and terminates without extending to the adjacent gate trench portion 40B in the array direction; and a second emitter region 12B which is provided to be in contact with the side wall of the gate trench portion 40B and terminates without extending to the adjacent gate trench portion 40A in the array direction.

Both of the gate trench portion 40A and the gate trench portion 40B of the present example are an example of the gate trench portion 40. The gate trench portions 40A and the gate trench portions 40B are alternately arrayed in the array direction. When the first emitter region 12A provided to be in contact with the side wall of the gate trench portion 40A is viewed as a center, the gate trench portion 40B adjacent to the gate trench portion 40A is an example of the first trench portion. When the second emitter region 12B provided to be in contact with the side wall of the gate trench portion 40B is viewed as a center, the gate trench portion 40A adjacent to the gate trench portion 40B is an example of the first trench portion.

The contact region 15 is provided from the end portion of the first emitter region 12A to the side wall of the gate trench portion 40B in the array direction, and provided from the end portion of the second emitter region 12B to the side wall of the gate trench portion 40A, and the first emitter regions 12A and the second emitter regions 12B are alternately provided in the extending direction.

In this manner, as each emitter region 12 is in contact with the contact region 15 in the array direction, the path of the hole current when the transistor portion 70 is in operation is not extended so that the effect similar to that of the semiconductor device 100 illustrated in FIG. 1A can be obtained. Further, in the present example, the emitter region 12 is provided to be in contact with the side walls of all the gate trench portions 40 such that the transistor characteristics can be improved.

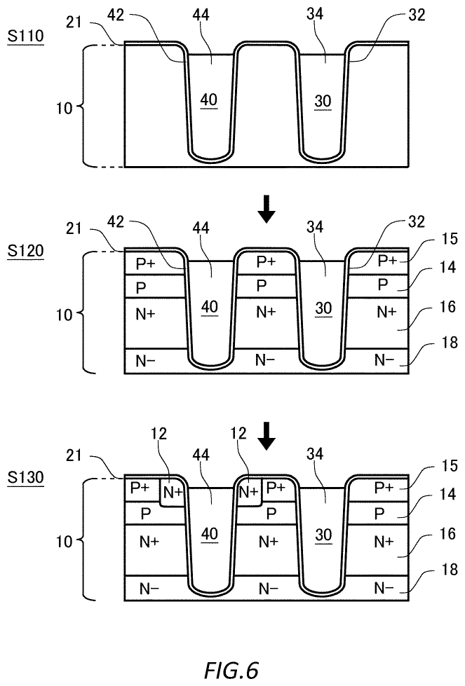

FIG. 6 is a diagram illustrating an example of a manufacturing method of the semiconductor device 100. Here, the process relevant to forming the emitter region 12 will be mainly described, and descriptions of other processes will be omitted.

In step S110, the plurality of trench portions are formed by etching the front surface 21 of the semiconductor substrate 10. The trench portion is formed by etching to the depth reaching a region to be the drift region 18 (a remaining region not provided with other doping regions in the semiconductor substrate 10). Then, an oxide film is formed on the side walls of the plurality of trench portions. The oxide film will be the dummy dielectric film 32 and the gate dielectric film 42. Then, the plurality of trench portions with the side walls covered by the dummy dielectric film 32 and the gate dielectric film 42 are filled with impurity-doped polysilicon or the like to form the dummy conductive portion 34 and the gate conductive portion 44, respectively. An excessive oxide film or the like deposited on the front surface 21 of the semiconductor substrate 10 is removed by etching to form the dummy trench portion 30 and the gate trench portion 40.

In step S120, the base region 14 and the contact region 15 are formed. The base region 14 and the contact region 15 are formed using the same mask by an ion implantation of the P type dopant to the front surface 21 of the semiconductor substrate 10. As an example, the dose amount of the base region 14 is 2E13 cm⁻² and the implantation acceleration is 400 kev, and the dose amount of the contact region 15 is 3E15 cm⁻² and the implantation acceleration is 120 kev. The dose amount may be appropriately adjusted to be a predetermined doping concentration.

When the accumulation region 16 if provided in the mesa portion, in step S120, the accumulation region 16 is formed by an ion implantation of the N type dopant to the front surface 21 of the semiconductor substrate 10. The accumulation region 16 may be formed using the same mask as that of the base region 14 and the contact region 15, or may be formed using a different mask.

Then, in step S130, the emitter region 12 is formed. The emitter region 12 is formed, after the contact region 15 is formed, by an ion implantation of the N type dopant to the front surface 21 of the semiconductor substrate 10 to invert a polarity of the P type region to the N type region. As an example, the dose amount of the emitter region 12 is 6E15 cm² and the implantation acceleration is 180 kev. The implantation acceleration to form the emitter region 12 is greater than the implantation acceleration to form the contact region 15. After the dopant is implanted, an annealing process is performed for heat diffusion. As an example, an annealing condition is at 970 degrees C. for 140 minutes. Note that the annealing process may be performed in each of steps S120 and S130, or may be performed in step S130 at all once.

The thickness of the emitter region 12 may be equal to or greater than 0.05 μm and equal to or smaller than 1.0 μm, and the thickness of the contact region 15 is equal to or greater than 0.05 μm and equal to or smaller than 2.0 μm. The thickness of the emitter region 12 of the present example is equal to or greater than 0.1 μm and equal to or smaller than 1.0 μm, and the thickness of the contact region 15 is equal to or greater than 0.1 μm and equal to or smaller than 1.0 μm. The thickness of the contact region 15 of the present example may be smaller than the thickness of the emitter region 12. As the emitter region 12 of the present example is formed by an implantation to invert a polarity of the contact region 15 of the P type to the N type, it is required to be formed with the implantation acceleration greater than the implantation acceleration to form the contact region 15 and to a region deeper than the lower end of the contact region 15. The smaller thickness of the contact region 15 suppresses the injection amount of holes to such that an excessive rise of the threshold voltage can be prevented.

In addition, as the emitter region 12 of the present example is formed by an implantation to invert a polarity of the contact region 15, the contact region 15 can be form using the same mask as that of the base region 14. Therefore, a mask to form the contact region 15 can be reduced and the fluctuation of patterning can also be suppressed. This can reduce the fluctuations of the lengths of the emitter region 12 and the contact region 15 in the extending direction and can suppress the fluctuation of dl/dt.

While the present invention has been described by way of the embodiments, the technical scope of the present invention is not limited to the above described embodiments. It is apparent to persons skilled in the art that various alterations or improvements can be made to the above described embodiments. It is also apparent from description of the claims that the embodiments to which such alterations or improvements are made can be included in the technical scope of the present invention.

It should be noted that the operations, procedures, steps, stages, and the like of each processing performed by an apparatus, system, program, and method shown in the claims, specification, or drawings can be realized in any order as long as the order is not indicated by “prior to,” “before,” or the like and as long as the output from a previous processing is not used in a later processing. Even if the operation flow is described using phrases such as “first” or “next” for the sake of convenience in the claims, specification, or drawings, it does not necessarily mean that the process must be performed in this order.

### EXPLANATION OF REFERENCES

10: semiconductor substrate, 11: well region, 12: emitter region, 14: base region, 15: contact region, 16: accumulation region, 18: drift region, 20: buffer region, 21: front surface, 22: collector region, 23: back surface, 24: collector electrode, 25: connection portion, 30: dummy trench portion, 32: dummy dielectric film, 34: dummy conductive portion, 38: interlayer dielectric film, 39: extending portion, 40: gate trench portion, 41: edge portion, 42: gate dielectric film, 44: gate conductive portion, 48: gate runner, 52: emitter electrode, 54: contact hole, 55: contact hole, 56: contact hole, 60: mesa portion, 70: transistor portion, 100: semiconductor device, 112: emitter region, 120: active portion, 1100: semiconductor device

What is claimed is:

1. A semiconductor device comprising:
a plurality of trench portions provided on a front surface of a semiconductor substrate and including a gate trench portion;
a drift region of a first conductivity type provided in the semiconductor substrate;
a base region of a second conductivity type provided above the drift region;
an emitter region of the first conductivity type provided above the base region and having a doping concentration higher than that of the drift region; and
a contact region of the second conductivity type provided above the base region and having a doping concentration higher than that of the base region,
wherein the emitter region is provided to be in contact with a side wall of the gate trench portion and terminates without extending to a first trench portion opposing to the gate trench portion from among the plurality of trench portions in a trench array direction, and
wherein the contact region is provided from an end portion of the emitter region to a side wall of the first trench portion in the trench array direction.

2. The semiconductor device according to claim 1, wherein
in a top view of the semiconductor substrate, the emitter region is discretely provided in a trench extending direction.

3. The semiconductor device according to claim 1, wherein
on the side wall of the gate trench portion, a length of the emitter region in the trench extending direction is greater than a length of the contact region in the trench extending direction.

4. The semiconductor device according to claim 1, wherein
a length of the emitter region in the trench array direction is equal to or greater than 0.1 μm and equal to or smaller than 1.0 μm.

5. The semiconductor device according to claim 1, wherein
a length of the emitter region in the trench extending direction is equal to or greater than 0.5 times and equal to or smaller than ten times a length of the contact region in a trench extending direction.

6. The semiconductor device according to claim 1, comprising an interlayer dielectric film provided above the front surface of the semiconductor substrate and including a contact hole,
wherein a terminating position of the emitter region in the trench array direction is below the contact hole.

7. The semiconductor device according to claim 1, wherein
a doping concentration of the emitter region is equal to or greater than 2E19 cm⁻³ and equal to or smaller than 4E20 cm⁻³.

8. The semiconductor device according to claim 1, wherein
in a depth direction of the semiconductor substrate, a thickness of the contact region is smaller than a thickness of the emitter region.

9. The semiconductor device according to claim 1, wherein
a doping concentration of the contact region is equal to or greater than 1E19 cm⁻³ and equal to or smaller than 2E20 cm⁻³.

10. The semiconductor device according to claim 1, wherein
the emitter region is provided to be spaced apart from the side wall of the first trench portion.

11. The semiconductor device according to claim 10, wherein
the plurality of trench portions include a dummy trench portion, and
the first trench portion is the dummy trench portion.

12. The semiconductor device according to claim 10, wherein
the first trench portion is the gate trench portion.

13. The semiconductor device according to claim 1, wherein
the emitter region includes:
a first emitter region provided to be in contact with the side wall of the gate trench portion and terminating without extending to the first trench portion in the trench array direction; and
a second emitter region provided to be in contact with the side wall of the first trench portion and terminating without extending to the gate trench portion in the trench array direction,
wherein the contact region is provide from an end portion of the first emitter region to the side wall of the first trench portion in the trench array direction, and provided from an end portion of the second emitter region to the side wall of the gate trench portion, and the first emitter region and the second emitter region are alternately provided in the trench extending direction.

14. The semiconductor device according to claim 13, wherein
the first trench portion is the gate trench portion.

15. A manufacturing method of a semiconductor device comprising:
forming a plurality of trench portions including a gate trench portion on a front surface of a semiconductor substrate;
forming a drift region of a first conductivity type in the semiconductor substrate;
forming a base region of a second conductivity type above the drift region;
forming an emitter region of the first conductivity type above the base region, the emitter region having a doping concentration higher than that of the drift region; and
forming a contact region of the second conductivity type above the base region, the contact region having a doping concentration higher than that of the base region,
wherein the emitter region is formed to be in contact with a side wall of the gate trench portion and terminates without extending to a first trench portion opposing to the gate trench portion in a trench array direction, and
the contact region is formed from an end portion of the emitter region to a side wall of the first trench portion in the trench array direction.

16. The manufacturing method of a semiconductor device according to claim 15, wherein
the contact region is formed by an ion implantation using the same mask as that of the base region.

17. The manufacturing method of a semiconductor device according to claim 15, wherein
the emitter region is formed, after forming the contact region, by an implantation to invert a polarity of a region of the second conductivity type to a region of the first conductivity type.
